(19) United States
(12) Patent Application Publication
(10) Pub. No.: US 2026/0282429 A1
(43) Pub. Date: Sep. 17, 2026

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventor: Yuki KOMATSU, Yokohama Kanagawa (JP)

(21) Appl. No.: 19/277,796

(22) Filed: Jul. 23, 2025

(30) Foreign Application Priority Data
Mar. 17, 2025 (JP) 2025-042382

(51) Int. Cl. H10D 30/65; H10D 30/01; H10D 30/60; H10D 62/10; H10D 64/27; H10D 89/60

(52) U.S. Cl. CPC H10D 30/65; H10D 30/601; H10D 62/102; H10D 62/116; H10D 62/124; H10D 64/518; H10D 89/931; H10D 30/0227; H10D 30/0281

(57) ABSTRACT

A semiconductor device includes a first semiconductor layer of a first conductivity type, a second semiconductor layer of a second conductivity type, a third semiconductor layer of the second conductivity type, a fourth semiconductor layer of the first conductivity type, a first insulating film located on the first semiconductor layer, a second insulating film located on the fourth semiconductor layer, an electrode located on the first insulating film, a first contact connected to the electrode, a second contact connected to the second semiconductor layer, a third contact connected to the third semiconductor layer, and a fourth contact extending through the second insulating film. The fourth semiconductor layer has a higher impurity concentration than the first semiconductor layer. The second insulating film is thicker than the first insulating film.

### CROSS-REFERENCE TO RELATED APPLICATIONS

This application is based upon and claims the benefit of priority from Japanese Patent Application No. 2025-042382, filed on Mar. 17, 2025; the entire contents of which are incorporated herein by reference.

### FIELD

Embodiments described herein relate generally to a semiconductor device.

### BACKGROUND

It is desirable for a semiconductor device to have ESD (electrostatic discharge) immunity. There is a method of improving the ESD immunity by providing a back gate region having a high impurity concentration in a body region, and by connecting a contact to the back gate region. As a result, holes that are generated by ESD can be discharged via the back gate region and the contact; and damage of the semiconductor device can be reduced. However, the source region is made narrower as the back gate region is made wider, which undesirably increases the on-resistance of the semiconductor device.

### BRIEF DESCRIPTION OF THE DRAWINGS

FIG. 1 is a plan view showing a semiconductor device according to a first embodiment;

FIG. 2 is a cross-sectional view along line A-A′ shown in FIG. 1;

FIG. 3 shows operations of the semiconductor device according to the first embodiment;

FIG. 4 is a cross-sectional view showing a semiconductor device according to a second embodiment;

FIG. 5 is a cross-sectional view showing a semiconductor device according to a third embodiment;

FIGS. 6A to 6C, FIGS. 7A to 7C, and FIG. 8 are process cross-sectional views showing a method for manufacturing the semiconductor device according to the third embodiment;

FIG. 9 is a cross-sectional view showing a semiconductor device according to a fourth embodiment;

FIGS. 10A to 10C and FIGS. 11A to 11C are process cross-sectional views showing a method for manufacturing the semiconductor device according to the fourth embodiment;

FIG. 12 is a cross-sectional view showing a semiconductor device according to a fifth embodiment;

FIG. 13 is a partial plan view showing a lower end vicinity of a common contact of the semiconductor device according to the fifth embodiment;

FIG. 14 is a cross-sectional view along line B-B′ shown in FIG. 13;

FIG. 15 is a cross-sectional view showing a semiconductor device according to a sixth embodiment;

FIG. 16 is a cross-sectional view showing a semiconductor device according to a seventh embodiment;

FIG. 17 is a cross-sectional view showing a semiconductor device according to an eighth embodiment; and

FIG. 18 is a cross-sectional view showing a semiconductor device according to a ninth embodiment.

### DETAILED DESCRIPTION

In general, according to one embodiment, a semiconductor device includes a first semiconductor layer of a first conductivity type, a second semiconductor layer of a second conductivity type, a third semiconductor layer of the second conductivity type, a fourth semiconductor layer of the first conductivity type, a first insulating film located on the first semiconductor layer, a second insulating film located on the fourth semiconductor layer, an electrode located on the first insulating film, a first contact connected to the electrode, a second contact connected to the second semiconductor layer, a third contact connected to the third semiconductor layer, and a fourth contact extending through the second insulating film. The second semiconductor layer is located on the first semiconductor layer. The third semiconductor layer is located on the first semiconductor layer and is separated from the second semiconductor layer. The fourth semiconductor layer contacts the first and third semiconductor layers, and has a higher impurity concentration than the first semiconductor layer. The second insulating film is thicker than the first insulating film. The fourth contact is connected to the fourth semiconductor layer.

In general, according to one embodiment, a semiconductor device includes a first semiconductor layer of a first conductivity type, a second semiconductor layer of a second conductivity type, a third semiconductor layer of the second conductivity type, a fourth semiconductor layer of the first conductivity type, a first insulating film located on the first semiconductor layer, a second insulating film located on the fourth semiconductor layer, an electrode located on the first insulating film, a first contact connected to the electrode, a second contact connected to the second semiconductor layer, and a third contact contacting the second insulating film. The second semiconductor layer is located on the first semiconductor layer. The third semiconductor layer is located on the first semiconductor layer and is separated from the second semiconductor layer. The fourth semiconductor layer contacts the first and third semiconductor layers, and has a higher impurity concentration than the first semiconductor layer. The second insulating film is thicker than the first insulating film. The third contact is connected to the third and fourth semiconductor layers.

### First Embodiment

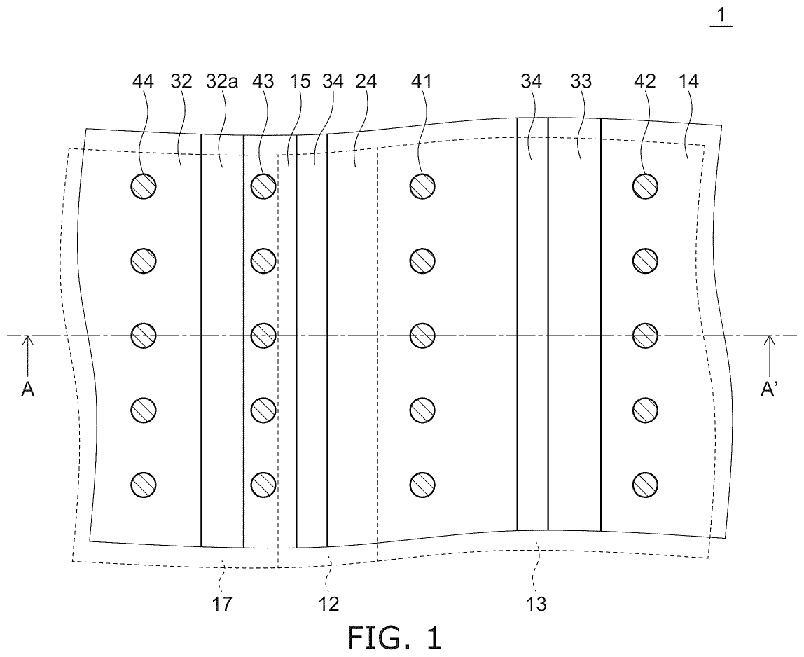

FIG. 1 is a plan view showing a semiconductor device according to an embodiment.

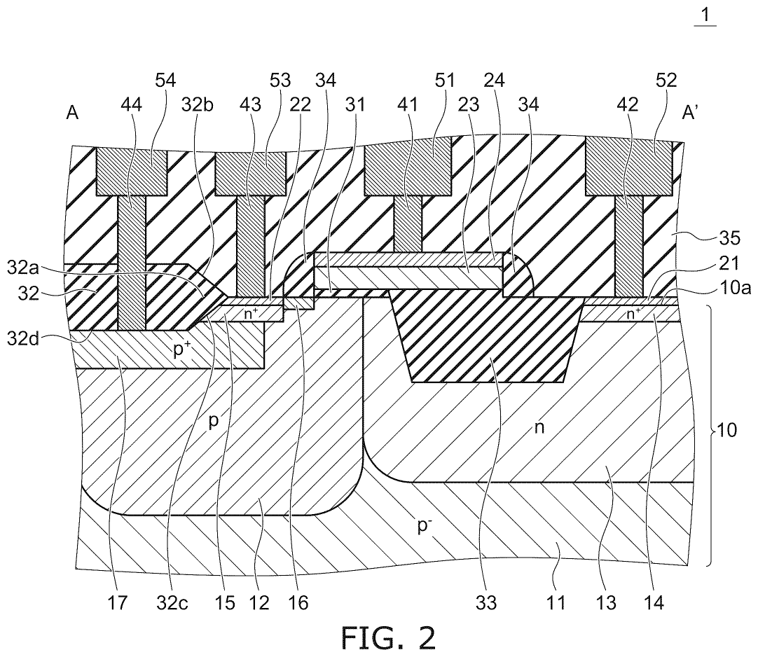

FIG. 2 is a cross-sectional view along line A-A′ shown in FIG. 1.

Wiring parts, inter-layer insulating films, and silicide layers, which will be described below, are not illustrated in FIG. 1.

The drawings are schematic and conceptual, and are appropriately enhanced and simplified. The dimensional ratios and positional relationships do not necessarily match exactly between the drawings, even for the same component. This is similar for the other drawings described below as well.

As shown in FIGS. 1 and 2, the semiconductor device 1 according to the embodiment is a DMOS (Double-Diffused Metal-Oxide-Semiconductor Field-Effect Transistor).

The semiconductor device 1 includes a semiconductor part 10, a drain silicide layer 21, a source silicide layer 22, a gate electrode 23, a gate silicide layer 24, a gate insulating film 31 (a first insulating film), a LOCOS (Local Oxidation of Silicon) film 32 (a second insulating film), a STI (Shallow Trench Isolation (element-separation insulating film)) 33, a sidewall 34, an inter-layer insulating film 35, a gate contact 41 (a first contact), a drain contact 42 (a second contact), a source contact 43 (a third contact), a back gate contact 44 (a fourth contact), a gate wiring part 51, a drain wiring part 52, a source wiring part 53, and a back gate wiring part 54. Although the direction from the semiconductor part 10 toward the inter-layer insulating film 35 is referred to as “up” or “above” and the opposite direction is referred to as “down” or “below” in the specification, these expressions are for convenience and are independent of the direction of gravity.

The semiconductor part 10 is made of a semiconductor material and is made of, for example, single-crystal silicon (Si). The semiconductor part 10 includes local impurities; and the conductivity type of each portion is set to a p-type (a first conductivity type) or an n-type (a second conductivity type). The semiconductor part 10 includes a base layer 11, a body layer 12, a drift layer 13, a drain layer 14, a source layer 15, a LDD (Lightly Doped Drain) layer 16, and a back gate layer 17 (a fourth semiconductor layer).

The conductivity type of the base layer 11 is the p⁻-type. The body layer 12 is located on a portion of the base layer 11. The conductivity type of the body layer 12 is the p-type. A first semiconductor layer includes the base layer 11 and the body layer 12. The “p⁻-type” means a lower effective impurity concentration than the “p-type”; and the “p⁺-type” means a higher effective impurity concentration than the “p-type”. The “effective impurity concentration” is the impurity concentration contributing to the conduction of the semiconductor material, and when both an impurity that forms acceptors and an impurity that forms donors are included in one region, refers to the concentration excluding the cancelled portion. This is similar for the n-type as well.

The drift layer 13 is located on another portion of the base layer 11 in contact with the body layer 12. The conductivity type of the drift layer 13 is the n-type. The drain layer 14 is located on the drift layer 13. The conductivity type of the drain layer 14 is the n⁺-type. A second semiconductor layer includes the drift layer 13 and the drain layer 14.

The source layer 15 is located on the body layer 12 and is separated from the drift layer 13 and the base layer 11. The conductivity type of the source layer 15 is the n⁺-type. The LDD layer 16 is located at the drain layer 14 side of the source layer 15 and contacts the source layer 15. The conductivity type of the LDD layer 16 is the n-type. A third semiconductor layer includes the source layer 15 and the LDD layer 16.

The back gate layer 17 is located on the body layer 12 and under the source layer 15. The lower surface of the back gate layer 17 contacts the body layer 12; and a portion of the upper surface of the back gate layer 17 contacts a portion of the lower surface of the source layer 15. The conductivity type of the back gate layer 17 is the p⁺-type. In other words, the impurity concentration of the back gate layer 17 is greater than the impurity concentration of the body layer 12.

The gate insulating film 31 is continuously located on the part of the body layer 12 between the LDD layer 16 and the drift layer 13 and on the part of the drift layer 13 between the body layer 12 and the STI 33. For example, the gate insulating film 31 is formed of silicon oxide.

The LOCOS film 32 is located on the back gate layer 17. The LOCOS film 32 is thicker than the gate insulating film 31. The LOCOS film 32 is made of silicon oxide and is formed by locally thermally oxidizing the upper surface of the semiconductor part 10. The LOCOS film 32 extends both above and below an upper surface 10a of the semiconductor part 10. The upper surface of the LOCOS film 32 is positioned higher than the upper surface of the gate insulating film 31; and the lower surface of the LOCOS film 32 is positioned lower than the lower surface of the gate insulating film 31.

An end part 32a of the LOCOS film 32 has a bird beak shape and includes an upper inclined surface 32b and a lower inclined surface 32c. A lower surface 32d of the LOCOS film 32 contacts the back gate layer 17; the lower inclined surface 32c contacts the back gate layer 17 and the source layer 15; and the upper inclined surface 32b contacts the inter-layer insulating film 35 described below. A silicon nitride film (not illustrated) may be located on the upper surface of the LOCOS film 32.

The STI 33 is located on the drift layer 13 between the drain contact 42 and the source contact 43 when viewed from above. The STI 33 is thicker than the gate insulating film 31. The part of the STI 33 that is positioned lower than the upper surface 10a of the semiconductor part 10 is thicker than the part of the STI 33 that is positioned higher than the upper surface 10a. The upper surface 10a of the semiconductor part 10 is, for example, the upper surface of the drift layer 13. The STI 33 contacts the drift layer 13 and the drain layer 14. The STI 33 is made of silicon oxide.

The drain silicide layer 21 is located on the drain layer 14 and connected to the drain layer 14. In the specification, “connected” means an electrical connection. The source silicide layer 22 is located on the source layer 15 and connected to the source layer 15. The upper surface of the source silicide layer 22 is at substantially the same height as the lower surface of the gate insulating film 31.

The gate electrode 23 is located on the gate insulating film 31 and on a portion of the STI 33. The gate silicide layer 24 is located on the gate electrode 23 and connected to the gate electrode 23. The sidewall 34 is located on the semiconductor part 10 and on the STI 33 at a side surface of the gate electrode 23. The sidewall 34 is made of an insulating material and is made of, for example, silicon oxide and silicon nitride.

For example, the inter-layer insulating film 35 is made of silicon oxide and is located above the semiconductor part 10, the LOCOS film 32, the gate electrode 23, etc. The gate contact 41 extends through the inter-layer insulating film 35 in the vertical direction; and the lower end of the gate contact 41 is connected to the gate silicide layer 24. The drain contact 42 extends through the inter-layer insulating film 35 in the vertical direction; and the lower end of the drain contact 42 is connected to the drain silicide layer 21. The source contact 43 extends through the inter-layer insulating film 35 in the vertical direction; and the lower end of the source contact 43 is connected to the source silicide layer 22. The back gate contact 44 extends through the inter-layer insulating film 35 in the vertical direction and extends through the LOCOS film 32; and the lower end of the back gate contact 44 is connected to the back gate layer 17. The back gate contact 44 contacts the inter-layer insulating film 35, the LOCOS film 32, and the back gate layer 17.

Although the gate contact 41, the drain contact 42, the source contact 43, and the back gate contact 44 are arranged in one column in FIGS. 1 and 2 to simplify the drawings, the actual product is not limited thereto. For example, the gate contact 41 may be located outside FIG. 1 and depthward or frontward with respect to the page surface in FIG. 2.

The gate wiring part 51 is located inside the inter-layer insulating film 35 and connected to the upper end of the gate contact 41. The drain wiring part 52 is located inside the inter-layer insulating film 35 and connected to the upper end of the drain contact 42. The source wiring part 53 is located inside the inter-layer insulating film 35 and connected to the upper end of the source contact 43. The back gate wiring part 54 is located inside the inter-layer insulating film 35 and connected to the upper end of the back gate contact 44.

Operations and effects of the semiconductor device 1 according to the embodiment will now be described.

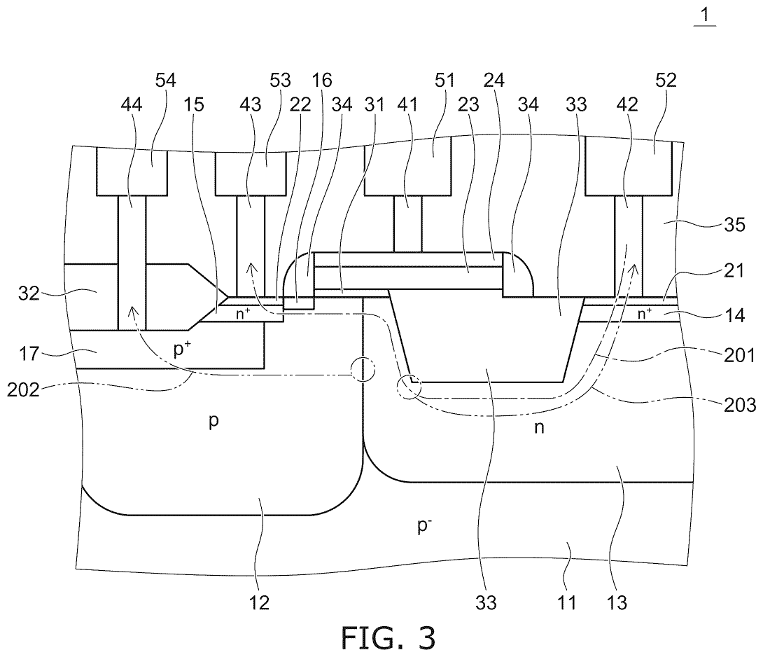

FIG. 3 shows operations of the semiconductor device according to the embodiment.

As shown in FIG. 3, when a potential that is less than a threshold is applied to the gate wiring part 51 in a state in which a reference potential, e.g., a ground potential, is applied to the back gate wiring part 54 and the source wiring part 53 and a positive potential is applied to the drain wiring part 52, a depletion layer is generated with the interfaces between the n-type drift layer 13 and the p⁻-type base layer 11 and between the n-type drift layer 13 and the p-type body layer 12 as starting points; and the semiconductor device 1 is set to an off-state. On the other hand, when a potential that is not less than the threshold is applied to the gate wiring part 51, an inversion layer is formed in the part of the body layer 12 contacting the gate insulating film 31; and a current flows along a path 201. As a result, the semiconductor device 1 is switched to an on-state.

When ESD from outside the semiconductor device 1 is applied via the drain wiring part 52 or the source wiring part 53, there are cases where an impact ionization phenomenon occurs at the vicinity of the interface between the drift layer 13 and the body layer 12 or at the vicinity of the corner of the STI 33. Holes that are generated by impact ionization flow along a path 202, flow into the p⁺-type back gate layer 17 via the p-type body layer 12, and are discharged outside the semiconductor device 1 via the back gate contact 44 and the back gate wiring part 54. Electrons that are generated by impact ionization flow along a path 203 and are discharged outside the semiconductor device 1 via the drift layer 13, the drain layer 14, the drain silicide layer 21, the drain contact 42, and the drain wiring part 52.

Thus, in the semiconductor device 1, the back gate layer 17 is located below the LOCOS film 32 and is connected to the back gate wiring part 54 via the back gate contact 44 extending through the LOCOS film 32. As a result, the holes that are generated by impact ionization can be recovered at a deep position in the semiconductor part 10 and can be prevented from flowing into the source layer 15. As a result, the ESD immunity is improved.

In contrast, if the back gate layer 17 is located in the upper layer part of the semiconductor part 10, the holes that are generated by impact ionization are recovered at a shallow position in the semiconductor part 10; and the amount of holes flowing into the source layer 15 is high. Therefore, there is a possibility that a parasitic n-p-n transistor made of the n-type drift layer 13, the p⁻-type base layer 11, the p-type body layer 12, and the n⁺-type source layer 15 may conduct, a current may flow and concentrate in the conducting part, and breakdown of the semiconductor device may occur.

In the semiconductor device 1, the back gate layer 17 is located below the source layer 15. Therefore, the area of the source layer 15 is not reduced by including the back gate layer 17. As a result, the on-resistance of the semiconductor device 1 is not increased.

In contrast, if the back gate layer 17 is located in the upper layer part of the semiconductor part 10, when the area of the back gate layer 17 is increased to improve the ESD immunity, the area of the source layer 15 is reduced commensurately. As a result, the on-resistance of the semiconductor device increases. Thus, when the back gate layer 17 is located in the upper layer part of the semiconductor part 10, the improvement of the ESD immunity and the reduction of the on-resistance undesirably have a trade-off and are difficult to realize together.

In the semiconductor device 1, the back gate contact 44 extends through the LOCOS film 32. As a result, the distance between the back gate contact 44 and the source contact 43 can be shortened even when it is necessary to provide the source wiring part 53 and the back gate wiring part 54 separately for circuit design reasons. As a result, the semiconductor device 1 can be smaller.

In contrast, when the back gate contact 44 and the source contact 43 are arranged with the LOCOS film 32 interposed, the distance between the back gate contact 44 and the source contact 43 is undesirably equal to or greater than the minimum size of the LOCOS film 32. Downsizing of the semiconductor device is inhibited in such a case because there is a limit for downsizing the LOCOS film due to process reasons.

### Second Embodiment

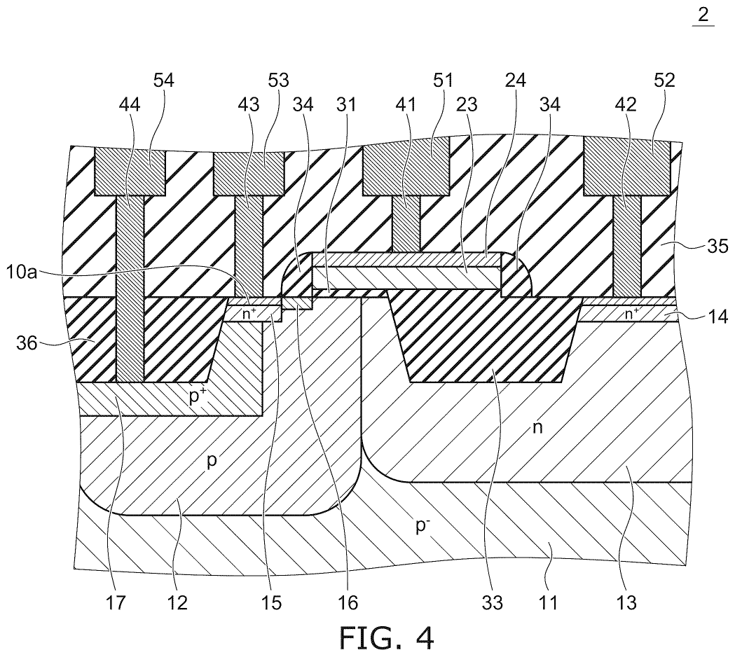

FIG. 4 is a cross-sectional view showing a semiconductor device according to an embodiment.

As shown in FIG. 4, the semiconductor device 2 according to the embodiment differs from the semiconductor device 1 according to the first embodiment in that a STI 36 is provided instead of the LOCOS film 32. The thickness of the part of the STI 36 positioned lower than the upper surface 10a of the semiconductor part 10 is greater than the thickness of the part of the STI 36 positioned higher than the upper surface 10a. The upper surface 10a of the semiconductor part 10 is, for example, the upper surface of the source layer 15.

As a result, holes can be recovered at a deeper position. Otherwise, the configuration, operations, and effects according to the embodiment are similar to those of the first embodiment.

### Third Embodiment

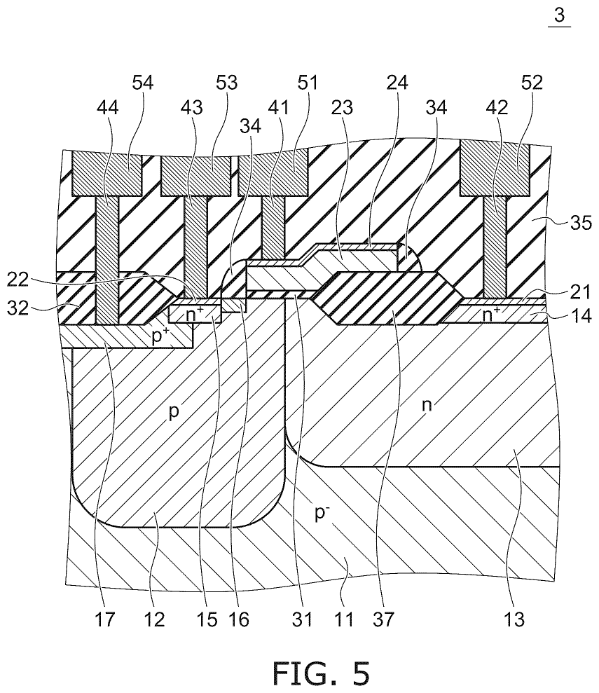

FIG. 5 is a cross-sectional view showing a semiconductor device according to an embodiment.

As shown in FIG. 5, the semiconductor device 3 according to the embodiment differs from the semiconductor device 1 according to the first embodiment in that a LOCOS film 37 is provided instead of the STI 33. In the semiconductor device 3, the part of the gate electrode 23 at the drain layer 14 side extends onto the LOCOS film 37. Also, a silicon nitride film (not illustrated) is located on the upper surface of the LOCOS film 32. The silicon nitride film also may be included in other embodiments.

A method for manufacturing the semiconductor device 3 according to the embodiment will now be described.

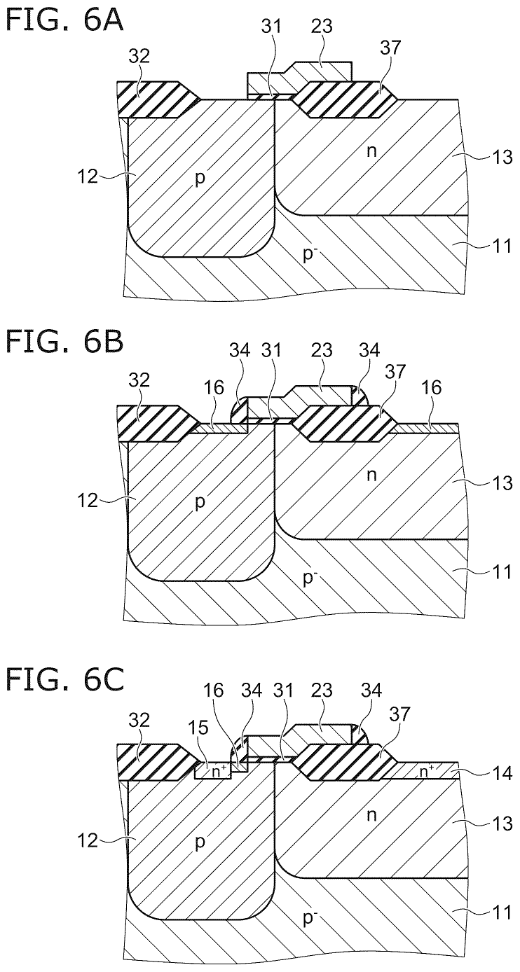

FIGS. 6A to 6C, FIGS. 7A to 7C, and FIG. 8 are process cross-sectional views showing the method for manufacturing the semiconductor device according to the embodiment.

First, the structure body shown in FIG. 6A is prepared.

Then, as shown in FIG. 6B, an impurity that forms donors is ion-implanted using the LOCOS film 32, the LOCOS film 37, and the gate electrode 23 as a mask. As a result, the n-type LDD layer 16 is formed in the upper layer part of the body layer 12 and the upper layer part of the drift layer 13. Also, the sidewall 34 is formed on the side surface of the gate electrode 23.

Continuing as shown in FIG. 6C, an impurity that forms donors is ion-implanted using the LOCOS film 32, the LOCOS film 37, the gate electrode 23, and the sidewall 34 as a mask. As a result, the n⁺-type source layer 15 is formed in the upper layer part of the body layer 12; and the n⁺-type drain layer 14 is formed in the upper layer part of the drift layer 13.

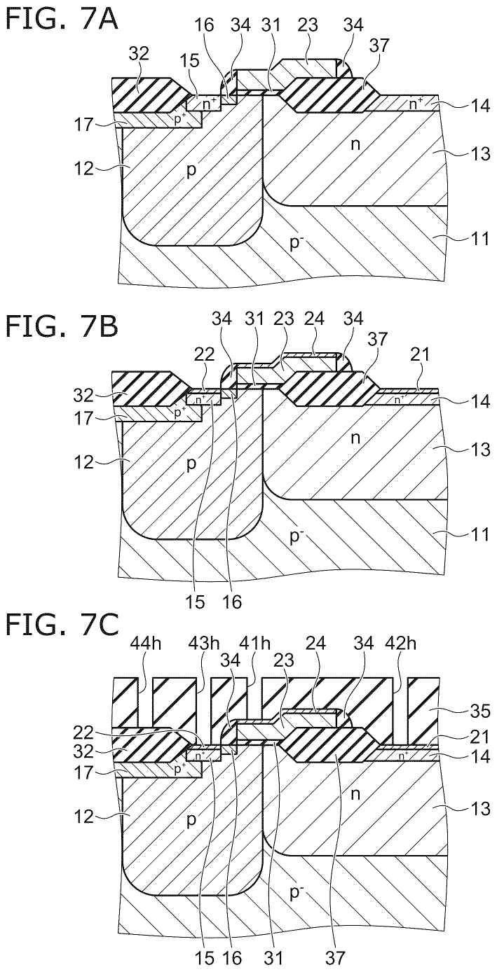

Then, as shown in FIG. 7A, an impurity that forms acceptors is locally ion-implanted. This ion implantation is performed using conditions such that the impurity is implanted deeper than the ion implantation when forming the source layer 15 and the drain layer 14. For example, the acceleration voltage is higher. As a result, the impurity extends through the LOCOS film 32 and reaches the body layer 12; and the p⁺-type back gate layer 17 is formed below the LOCOS film 32 and the source layer 15.

Continuing as shown in FIG. 7B, the exposed parts of silicon are silicided. As a result, the drain silicide layer 21 is formed in the upper layer part of the drain layer 14; the source silicide layer 22 is formed in the upper layer part of the source layer 15; and the gate silicide layer 24 is formed in the upper layer part of the gate electrode 23.

Then, as shown in FIG. 7C, a first layer of the inter-layer insulating film 35 is formed. Then, the first layer of the inter-layer insulating film 35 is selectively removed by, for example, lithography and RIE (Reactive Ion Etching). Contact holes 41h, 42h, 43h, and 44h are formed thereby.

The RIE is performed using conditions such that the etching rate of silicon oxide is greater than the etching rate of silicide and the etching rate of silicon nitride. As a result, the contact hole 41h reaches and terminates at the gate silicide layer 24; the contact hole 42h reaches and terminates at the drain silicide layer 21; the contact hole 43h reaches and terminates at the source silicide layer 22; and the contact hole 44h reaches and terminates at the silicon nitride film on the LOCOS film 32.

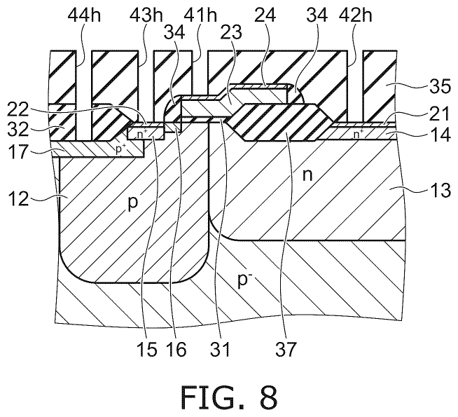

Then, RIE is performed again as shown in FIG. 8. The RIE is performed using conditions such that the etching rate of silicon oxide and the etching rate of silicon nitride are greater than the etching rate of silicon and the etching rate of silicide. As a result, the contact hole 44h extends through the LOCOS film 32 and reaches and terminates at the back gate layer 17. At this time, the contact holes 41h, 42h, and 43h substantially do not extend.

Continuing as shown in FIG. 5, the contact holes 41h, 42h, 43h, and 44h are filled with a conductive material. As a result, the gate contact 41 is formed inside the contact hole 41h; the drain contact 42 is formed inside the contact hole 42h; the source contact 43 is formed inside the contact hole 43h; and the back gate contact 44 is formed inside the contact hole 44h. The back gate contact 44 contacts the inter-layer insulating film 35, the LOCOS film 32, and the back gate layer 17.

Then, a second layer of the inter-layer insulating film 35 is formed; and the gate wiring part 51, the drain wiring part 52, the source wiring part 53, and the back gate wiring part 54 are formed inside the second layer. Thus, the semiconductor device 3 according to the embodiment is manufactured. Otherwise, the configuration, operations, and effects according to the embodiment are similar to those of the first embodiment.

### Fourth Embodiment

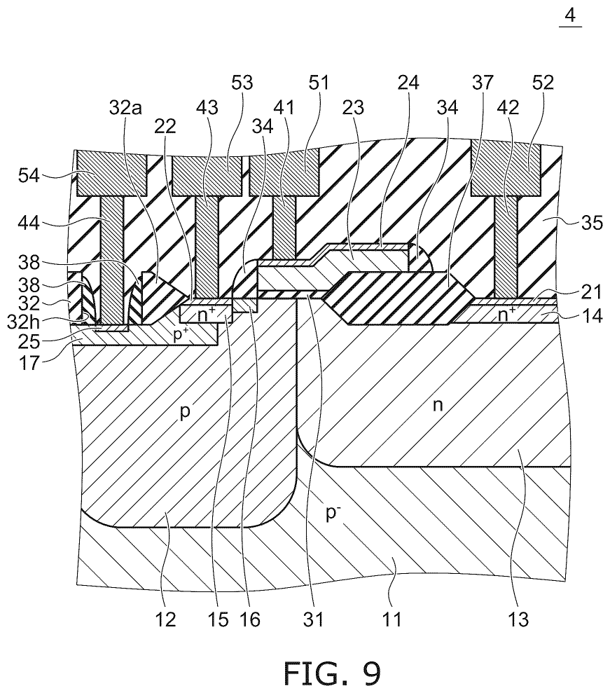

FIG. 9 is a cross-sectional view showing a semiconductor device according to an embodiment.

As shown in FIG. 9, the semiconductor device 4 according to the embodiment differs from the semiconductor device 3 according to the third embodiment in that a sidewall 38 and a portion of the inter-layer insulating film 35 are interposed between the LOCOS film 32 and the back gate contact 44; and a back gate silicide layer 25 is formed at a portion of the upper surface of the back gate layer 17.

In the semiconductor device 4, a through-hole 32h is formed in the LOCOS film 32; the sidewall 38 is located on the inner surface of the through-hole 32h; a portion of the inter-layer insulating film 35 is surrounded with the sidewall 38 inside the through-hole 32h; and the back gate contact 44 extends through the portion of the inter-layer insulating film 35. Accordingly, the back gate contact 44 is separated from the LOCOS film 32.

A method for manufacturing the semiconductor device 4 according to the embodiment will now be described.

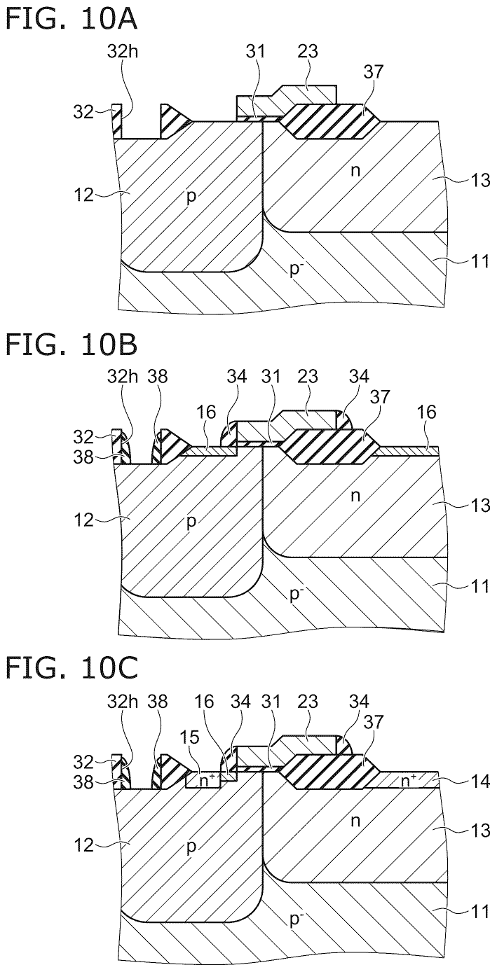

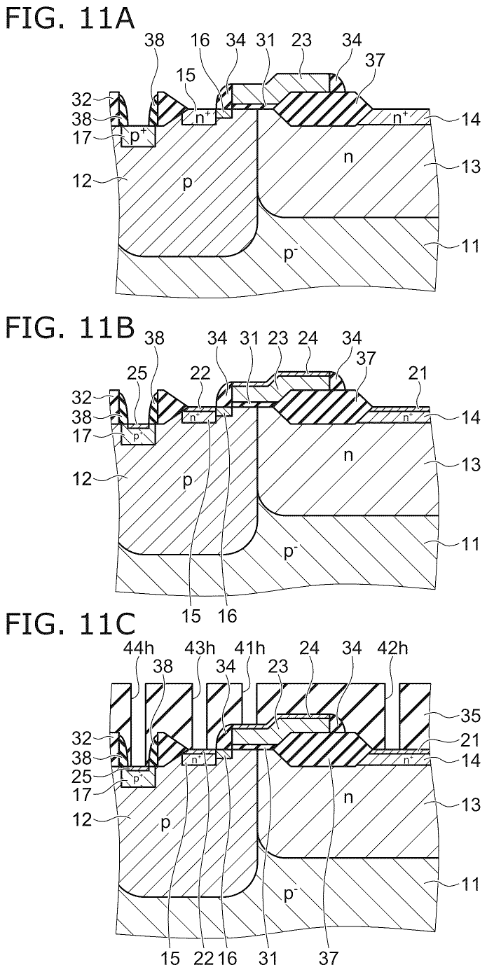

FIGS. 10A to 10C and FIGS. 11A to 11C are process cross-sectional views showing the method for manufacturing the semiconductor device according to the embodiment.

First, the structure body shown in FIG. 6A is made.

Then, as shown in FIG. 10A, the through-hole 32h is formed in the LOCOS film 32 by, for example, lithography and RIE. The body layer 12 is exposed at the bottom surface of the through-hole 32h.

Continuing as shown in FIG. 10B, an impurity that forms donors is ion-implanted using the LOCOS film 32, the LOCOS film 37, and the gate electrode 23 as a mask. As a result, the n-type LDD layer 16 is formed in the upper layer part of the body layer 12 and the upper layer part of the drift layer 13. Then, the sidewall 34 is formed on the side surface of the gate electrode 23; and the sidewall 38 is formed on the inner surface of the through-hole 32h. At this time, the through-hole 32h is shielded with a mask (not illustrated) beforehand.

Then, as shown in FIG. 10C, an impurity that forms donors is ion-implanted using the LOCOS film 32, the LOCOS film 37, the gate electrode 23, and the sidewall 34 as a mask. As a result, the n⁺-type source layer 15 is formed in the upper layer part of the body layer 12; and the n⁺-type drain layer 14 is formed in the upper layer part of the drift layer 13. Subsequently, the mask that shields the through-hole 32h is removed.

Continuing as shown in FIG. 11A, an impurity that forms acceptors is locally ion-implanted using the LOCOS film 32 and the sidewall 38 as a mask. The ion implantation is performed using conditions similar to the ion implantation when forming the source layer 15 and the drain layer 14. As a result, the impurity reaches the body layer 12 via the through-hole 32h of the LOCOS film 32; and the p⁺-type back gate layer 17 is formed in the region of the body layer 12 directly under the through-hole 32h.

Then, as shown in FIG. 11B, the exposed parts of silicon are silicided. As a result, the drain silicide layer 21 is formed in the upper layer part of the drain layer 14; the source silicide layer 22 is formed in the upper layer part of the source layer 15; the gate silicide layer 24 is formed in the upper layer part of the gate electrode 23; and the back gate silicide layer 25 is formed in the part of the back gate layer 17 exposed inside the through-hole 32h.

Continuing as shown in FIG. 11C, the first layer of the inter-layer insulating film 35 is formed. The inter-layer insulating film 35 also is located inside the through-hole 32h of the LOCOS film 32. Then, the contact holes 41h, 42h, 43h, and 44h are formed in the first layer of the inter-layer insulating film 35. At this time, the contact hole 44h extends through the part of the inter-layer insulating film 35 located inside the through-hole 32h, and reaches and terminates at the back gate silicide layer 25. The subsequent processes are similar to those of the third embodiment. Thus, the semiconductor device 4 according to the embodiment is manufactured.

According to the embodiment, the ion implantation to form the back gate layer 17 is performed via the through-hole 32h of the LOCOS film 32, and so the acceleration voltage of the ion implantation can be lower than that of the third embodiment.

As a result, for example, when an n-channel DMOS and a p-channel DMOS are simultaneously formed, the p⁺-type back gate layer 17 of the n-channel DMOS can be formed by utilizing the process of forming the p⁺-type drain layer and the source layer of the p-channel DMOS. Also, the n⁺-type back gate layer of the p-channel DMOS can be formed by utilizing the process of forming the n⁺-type drain layer 14 and the source layer 15 of the n-channel DMOS. As a result, the number of ion implantations can be reduced, and the manufacturing cost can be reduced. Otherwise, the configuration, manufacturing method, operations, and effects according to the embodiment are similar to those of the fourth embodiment.

### Fifth Embodiment

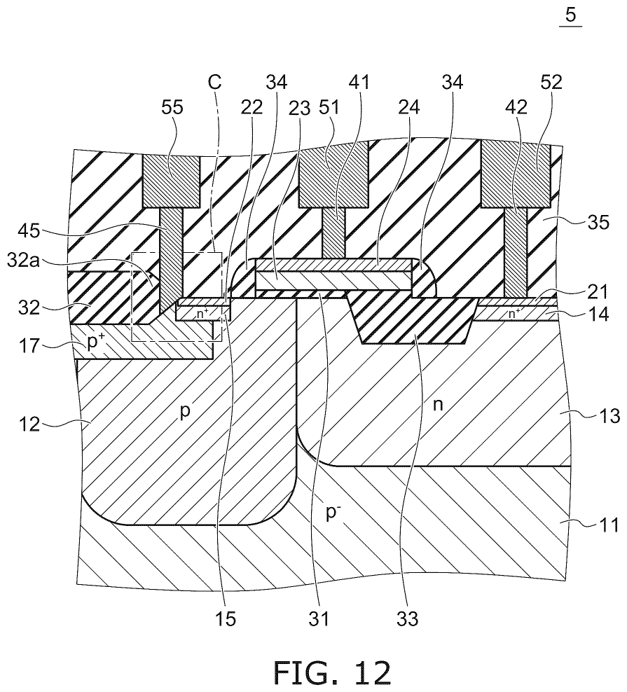

FIG. 12 is a cross-sectional view showing a semiconductor device according to an embodiment.

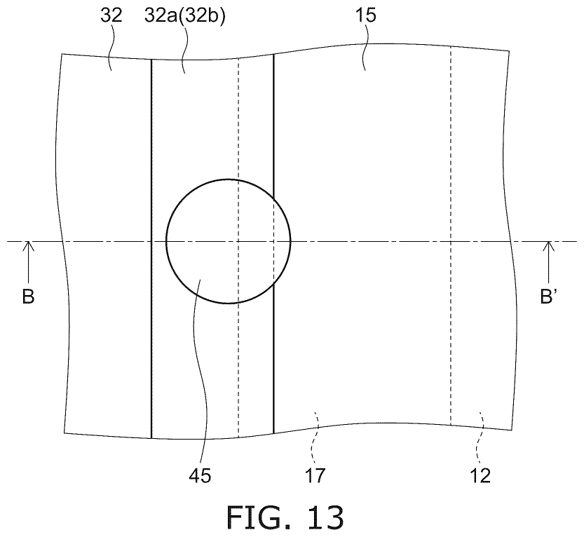

FIG. 13 is a partial plan view showing the lower end vicinity of a common contact of the semiconductor device according to the embodiment.

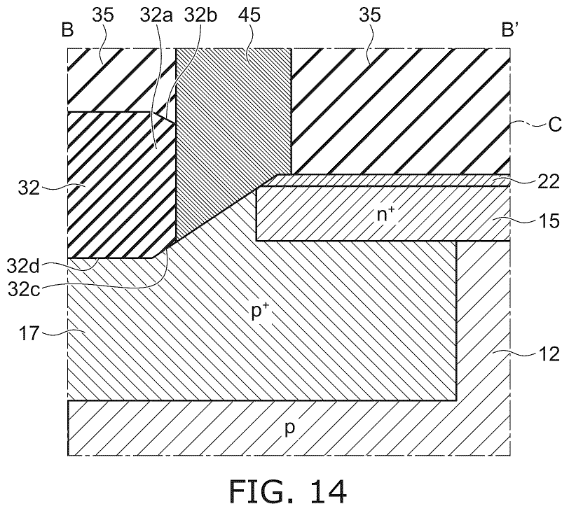

FIG. 14 is a cross-sectional view along line B-B′ shown in FIG. 13.

FIG. 14 corresponds to region C of FIG. 12. The inter-layer insulating film 35 and the source silicide layer 22 are not illustrated in FIG. 13.

As shown in FIGS. 12 to 14, the semiconductor device 5 according to the embodiment differs from the semiconductor device 1 according to the first embodiment in that a common contact 45 is provided instead of the source contact 43 and the back gate contact 44; and a common wiring part 55 is provided instead of the source wiring part 53 and the back gate wiring part 54.

The common contact 45 contacts the end part 32a of the LOCOS film 32 and juts into the end part 32a, but is not completely surrounded with the LOCOS film 32 when viewed from above. The lower end of the common contact 45 contacts and is connected to the source silicide layer 22, the source layer 15, and the back gate layer 17. The upper end of the common contact 45 is connected to the common wiring part 55.

According to the embodiment, even when the source wiring part and the back gate wiring part are shared as the common wiring part 55 due to circuit design reasons, holes can be recovered from a deep position of the semiconductor part 10 by positioning the back gate layer 17 below the source layer 15 and by positioning the lower end of the common contact 45 at the vicinity of the lower surface 32d of the LOCOS film 32. As a result, the ESD immunity is improved. Otherwise, the configuration, operations, and effects according to the embodiment are similar to those of the first embodiment.

### Sixth Embodiment

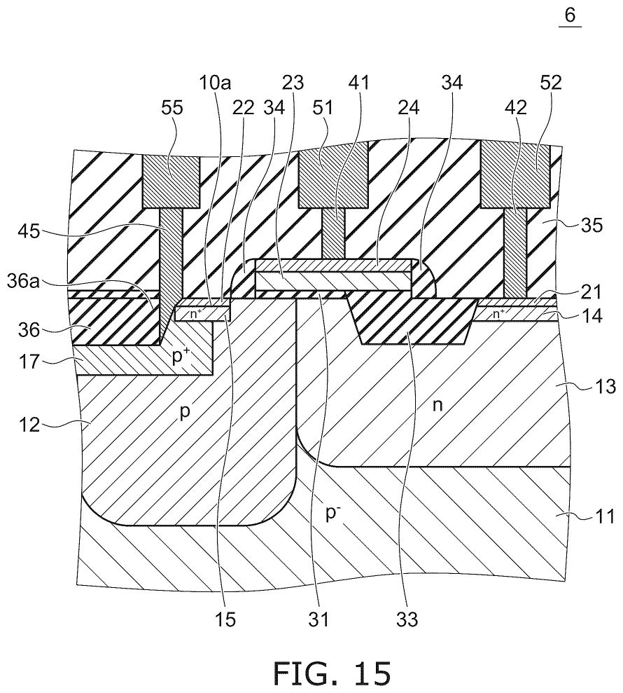

FIG. 15 is a cross-sectional view showing a semiconductor device according to an embodiment.

As shown in FIG. 15, the semiconductor device 6 according to the embodiment differs from the semiconductor device 5 according to the fifth embodiment in that the STI 36 is provided instead of the LOCOS film 32. The thickness of the part of the STI 36 positioned lower than the upper surface 10a of the semiconductor part 10 is greater than the thickness of the part of the STI 36 positioned higher than the upper surface 10a.

The common contact 45 contacts an end part 36a of the STI 36 and juts into the end part 36a, but is not completely surrounded with the STI 36 when viewed from above. The lower end of the common contact 45 contacts and is connected to the source silicide layer 22, the source layer 15, and the back gate layer 17. As a result, holes can be recovered at a deeper position. Otherwise, the configuration, operations, and effects according to the embodiment are similar to those of the fifth embodiment.

### Seventh Embodiment

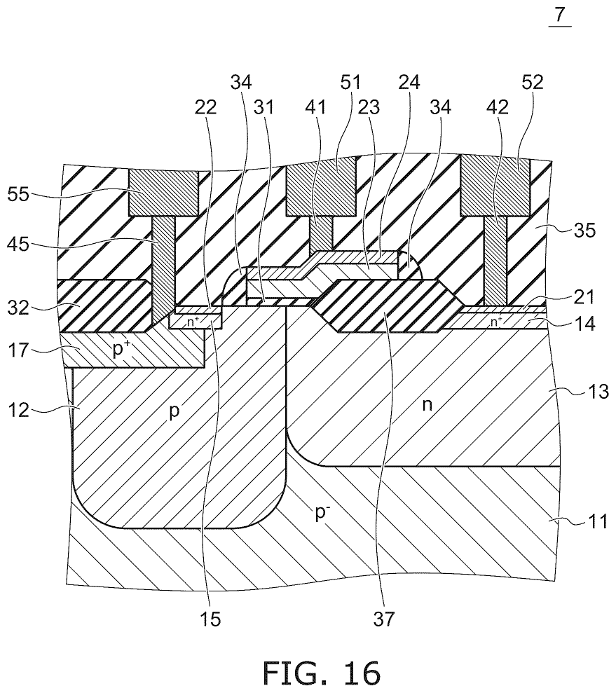

FIG. 16 is a cross-sectional view showing a semiconductor device according to an embodiment.

As shown in FIG. 16, the semiconductor device 7 according to the embodiment differs from the semiconductor device 5 according to the fifth embodiment in that the LOCOS film 37 is provided instead of the STI 33. In the semiconductor device 7, the part of the gate electrode 23 at the drain layer 14 side extends onto the LOCOS film 37. Otherwise, the configuration, operations, and effects according to the embodiment are similar to those of the fifth embodiment.

### Eighth Embodiment

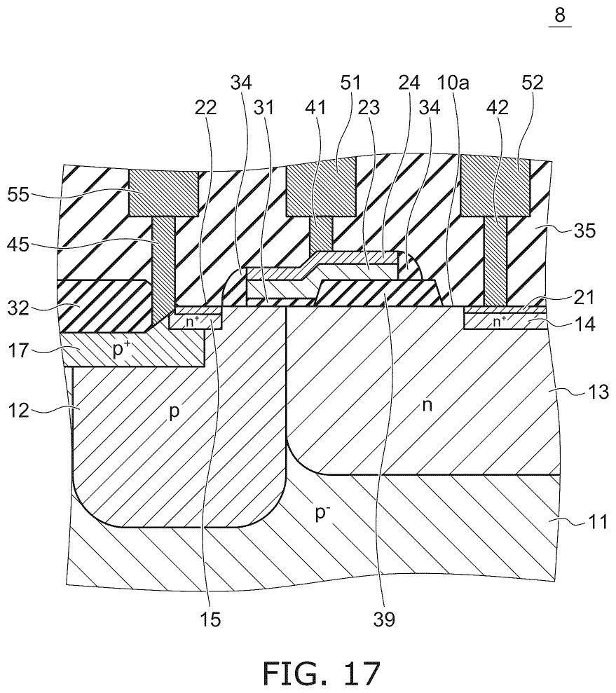

FIG. 17 is a cross-sectional view showing a semiconductor device according to an embodiment.

As shown in FIG. 17, the semiconductor device 8 according to the embodiment differs from the semiconductor device 5 according to the fifth embodiment in that a step oxide film 39 is provided instead of the STI 33. The thickness of the part of the step oxide film 39 positioned above the upper surface 10a of the semiconductor part 10 is greater than the thickness of the part of the step oxide film 39 positioned below the upper surface 10a. The upper surface 10a of the semiconductor part 10 is, for example, the upper surface of the drift layer 13. In the semiconductor device 8, the part of the gate electrode 23 at the drain layer 14 side extends onto the step oxide film 39. Otherwise, the configuration, operations, and effects according to the embodiment are similar to those of the fifth embodiment.

### Ninth Embodiment

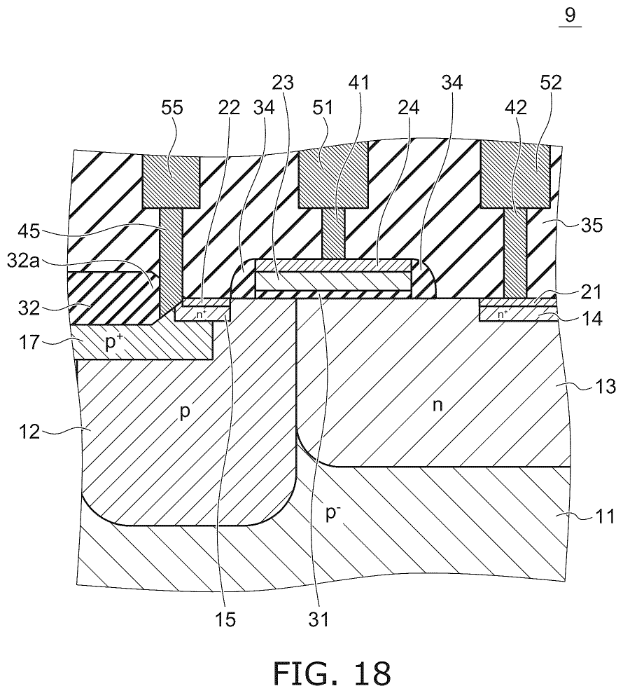

FIG. 18 is a cross-sectional view showing a semiconductor device according to an embodiment.

As shown in FIG. 18, the semiconductor device 9 according to the embodiment differs from the semiconductor device 5 according to the fifth embodiment in that the STI 33 is not included. As a result, a linear current path is formed between the drain layer 14 and the source layer 15, and so the on-resistance is reduced. However, the ESD immunity is improved when insulating members such as the STI 33, the LOCOS film 37, the step oxide film 39, etc., are located between the drain layer 14 and the source layer 15 and current paths are formed to detour around the insulating members, as in the first to eighth embodiments. Otherwise, the configuration, operations, and effects according to the embodiment are similar to those of the fifth embodiment.

Although an n-channel DMOS is described as an example in the embodiments above, the invention also is applicable to a p-channel DMOS. In other words, the base layer 11 may be of the n⁻-type; the body layer 12 may be of the n-type; the drift layer 13 may be of the p-type; the drain layer 14 may be of the p⁺-type; the source layer 15 may be of the p⁺-type; the LDD layer 16 may be of the p-type; and the back gate layer 17 may be of the n⁺-type.

According to the embodiments above, a semiconductor device can be realized in which the ESD immunity is high.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions. Additionally, the embodiments described above can be combined mutually.

Embodiments include the following aspects.

### Note 1

A semiconductor device, comprising:
a first semiconductor layer of a first conductivity type;
a second semiconductor layer located on the first semiconductor layer, the second semiconductor layer being of a second conductivity type;
a third semiconductor layer located on the first semiconductor layer and separated from the second semiconductor layer, the third semiconductor layer being of the second conductivity type;
a fourth semiconductor layer contacting the first and third semiconductor layers, the fourth semiconductor layer being of the first conductivity type and having a higher impurity concentration than the first semiconductor layer;
a first insulating film located on the first semiconductor layer;
a second insulating film located on the fourth semiconductor layer, the second insulating film being thicker than the first insulating film;
an electrode located on the first insulating film;
a first contact connected to the electrode;
a second contact connected to the second semiconductor layer;
a third contact connected to the third semiconductor layer; and
a fourth contact extending through the second insulating film, the fourth contact being connected to the fourth semiconductor layer.

### Note 2

The device according to note 1, wherein the fourth contact contacts the second insulating film.

### Note 3

The device according to note 1, wherein the fourth contact is separated from the second insulating film.

### Note 4

A semiconductor device, comprising:
a first semiconductor layer of a first conductivity type;
a second semiconductor layer located on the first semiconductor layer, the second semiconductor layer being of a second conductivity type;
a third semiconductor layer located on the first semiconductor layer and separated from the second semiconductor layer, the third semiconductor layer being of the second conductivity type;
a fourth semiconductor layer contacting the first and third semiconductor layers, the fourth semiconductor layer being of the first conductivity type and having a higher impurity concentration than the first semiconductor layer;
a first insulating film located on the first semiconductor layer;
a second insulating film located on the fourth semiconductor layer, the second insulating film being thicker than the first insulating film;
an electrode located on the first insulating film;
a first contact connected to the electrode;
a second contact connected to the second semiconductor layer; and
a third contact contacting the second insulating film, the third contact being connected to the third and fourth semiconductor layers.

### Note 5

The device according to any one of notes 1 to 4, wherein
the fourth semiconductor layer is located lower than the third semiconductor layer.

### Note 6

The device according to any one of notes 1 to 5, wherein
an upper surface of the second insulating film is positioned higher than an upper surface of the first insulating film, and
a lower surface of the second insulating film is positioned lower than a lower surface of the first insulating film.

### Note 7

The device according to any one of notes 1 to 5, wherein
a thickness of a part of the second insulating film positioned lower than an upper surface of the third semiconductor layer is greater than a thickness of a part of the second insulating film positioned higher than the upper surface of the third semiconductor layer.

### Note 8

The device according to any one of notes 1 to 7, further comprising:
a third insulating film located on the second semiconductor layer between the second contact and the third contact when viewed from above,
the third insulating film being thicker than the first insulating film.

### Note 9

The device according to note 8, wherein
a thickness of a part of the third insulating film positioned lower than an upper surface of the second semiconductor layer is greater than a thickness of a part of the third insulating film positioned higher than the upper surface of the second semiconductor layer.

### Note 10

The device according to note 8, wherein
an upper surface of the third insulating film is positioned higher than an upper surface of the first insulating film, and
a lower surface of the third insulating film is positioned lower than a lower surface of the first insulating film.

### Note 11

The device according to note 8, wherein
a thickness of a part of the third insulating film positioned higher than an upper surface of the second semiconductor layer is greater than a thickness of a part of the third insulating film positioned lower than the upper surface of the second semiconductor layer.

What is claimed is:

1. A semiconductor device, comprising:
a first semiconductor layer of a first conductivity type;
a second semiconductor layer located on the first semiconductor layer, the second semiconductor layer being of a second conductivity type;
a third semiconductor layer located on the first semiconductor layer and separated from the second semiconductor layer, the third semiconductor layer being of the second conductivity type;
a fourth semiconductor layer contacting the first and third semiconductor layers, the fourth semiconductor layer being of the first conductivity type and having a higher impurity concentration than the first semiconductor layer;
a first insulating film located on the first semiconductor layer;
a second insulating film located on the fourth semiconductor layer, the second insulating film being thicker than the first insulating film;
an electrode located on the first insulating film;
a first contact connected to the electrode;
a second contact connected to the second semiconductor layer;
a third contact connected to the third semiconductor layer; and
a fourth contact extending through the second insulating film, the fourth contact being connected to the fourth semiconductor layer.

2. The device according to claim 1, wherein
the fourth contact contacts the second insulating film.

3. The device according to claim 1, wherein
the fourth contact is separated from the second insulating film.

4. The device according to claim 1, wherein
the fourth semiconductor layer is located lower than the third semiconductor layer.

5. The device according to claim 1, wherein
an upper surface of the second insulating film is positioned higher than an upper surface of the first insulating film, and
a lower surface of the second insulating film is positioned lower than a lower surface of the first insulating film.

6. The device according to claim 1, wherein
a thickness of a part of the second insulating film positioned lower than an upper surface of the third semiconductor layer is greater than a thickness of a part of the second insulating film positioned higher than the upper surface of the third semiconductor layer.

7. The device according to claim 1, further comprising:
a third insulating film located on the second semiconductor layer between the second contact and the third contact when viewed from above,
the third insulating film being thicker than the first insulating film.

8. The device according to claim 7, wherein
a thickness of a part of the third insulating film positioned lower than an upper surface of the second semiconductor layer is greater than a thickness of a part of the third insulating film positioned higher than the upper surface of the second semiconductor layer.

9. The device according to claim 7, wherein
an upper surface of the third insulating film is positioned higher than an upper surface of the first insulating film, and
a lower surface of the third insulating film is positioned lower than a lower surface of the first insulating film.

10. The device according to claim 7, wherein
a thickness of a part of the third insulating film positioned higher than an upper surface of the second semiconductor layer is greater than a thickness of a part of the third insulating film positioned lower than the upper surface of the second semiconductor layer.

11. A semiconductor device, comprising:
a first semiconductor layer of a first conductivity type;
a second semiconductor layer located on the first semiconductor layer, the second semiconductor layer being of a second conductivity type;
a third semiconductor layer located on the first semiconductor layer and separated from the second semiconductor layer, the third semiconductor layer being of the second conductivity type;
a fourth semiconductor layer contacting the first and third semiconductor layers, the fourth semiconductor layer being of the first conductivity type and having a higher impurity concentration than the first semiconductor layer;
a first insulating film located on the first semiconductor layer;
a second insulating film located on the fourth semiconductor layer, the second insulating film being thicker than the first insulating film;
an electrode located on the first insulating film;
a first contact connected to the electrode;
a second contact connected to the second semiconductor layer; and
a third contact contacting the second insulating film, the third contact being connected to the third and fourth semiconductor layers.

12. The device according to claim 11, wherein
the fourth semiconductor layer is located lower than the third semiconductor layer.

13. The device according to claim 11, wherein
an upper surface of the second insulating film is positioned higher than an upper surface of the first insulating film, and
a lower surface of the second insulating film is positioned lower than a lower surface of the first insulating film.

14. The device according to claim 11, wherein
a thickness of a part of the second insulating film positioned lower than an upper surface of the third semiconductor layer is greater than a thickness of a part of the second insulating film positioned higher than the upper surface of the third semiconductor layer.

15. The device according to claim 11, further comprising:
a third insulating film located on the second semiconductor layer between the second contact and the third contact when viewed from above,
the third insulating film being thicker than the first insulating film.

16. The device according to claim 15, wherein
a thickness of a part of the third insulating film positioned lower than an upper surface of the second semiconductor layer is greater than a thickness of a part of the third insulating film positioned higher than the upper surface of the second semiconductor layer.

17. The device according to claim 15, wherein
an upper surface of the third insulating film is positioned higher than an upper surface of the first insulating film, and
a lower surface of the third insulating film is positioned lower than a lower surface of the first insulating film.

18. The device according to claim 15, wherein
a thickness of a part of the third insulating film positioned higher than an upper surface of the second semiconductor layer is greater than a thickness of a part of the third insulating film positioned lower than the upper surface of the second semiconductor layer.
